(19) United States
(12) Patent Application Publication
(10) Pub. No.: US 2026/0092003 A1
(43) Pub. Date: Apr. 2, 2026

(54) GLASS RING MADE OF MULTI-COMPONENT GLASS AND METHOD AND DEVICE FOR PRODUCING SAID GLASS RING

(71) Applicant: Heraeus Quarzglas GmbH & Co. KG, Hanau (DE)

(72) Inventors: Christian SCHENK, Kleinostheim (DE); Markus KÖNIG, Kleinostheim (DE); Michael WENTZEL, Kleinostheim (DE)

(21) Appl. No.: 19/341,957

(22) Filed: Sep. 26, 2025

(30) Foreign Application Priority Data
Sep. 27, 2024 (EP) 24203101.1

(51) Int. Cl. C03B 19/02; H01J 37/32

(52) U.S. Cl. CPC C03B 19/02; H01J 37/32642; H01J 2237/334

(57) ABSTRACT

The production of near-net geometry rings from a multi-component glass, in particular thick-walled rings with wall thicknesses of more than 10 mm. For this purpose, a ring-shaped blank is first produced from the multi-component glass using a casting process, in which a casting strand made of a glass melt of the multi-component glass is fed into a casting mold with a ring-shaped casting cavity running around a center axis. The casting strand hitting an impact zone diverges into a right-hand substream and a left-hand substream, with the substreams converging at a merging zone in the casting cavity and filling the casting cavity over at least part of its height. After the glass melt cools, a ring-shaped blank is obtained, which is further processed into a glass ring made of the multi-component glass.

### CROSS-REFERENCE TO RELATED APPLICATION

This application claims priority pursuant to 35 U.S.C. 119 (a) to European Application No. 24203101.1, filed Sep. 27, 2024, which application is incorporated herein by reference in its entirety.

### BACKGROUND

The invention relates to a method for producing a glass ring from multi-component glass, in particular for producing large, preferably thick-walled glass rings. In addition, the invention relates to a device for producing a glass ring from multi-component glass.

The invention also relates to a glass ring made of multi-component glass. Such glass rings are used, for example, in semiconductor manufacturing as so-called “plasma etching rings” to hold semiconductor wafers in plasma etching systems.

Plasma-assisted manufacturing processes, such as plasma-assisted dry etching, also referred to as “plasma etching” for short, is a technology for producing ultrafine structures of semiconductor components, high-resolution displays, and in solar cell manufacturing. Plasma etching is carried out in a plasma chamber which is flushed with etching gas at low pressure and in which a reactive etching plasma is generated. For etching silicon-based structures, halogen-containing etching gases are commonly used, such as CF₄, C₂F₆, C₃F₈, C₄F₆, CH₂F₂, C₄F₈, NF₃, SF₆, HF, HCl, or HBr. The components of the plasma chamber are cleaned from time to time, which is usually also done using plasma and fluorine-containing etching gas.

The rings exposed to the plasma and etching gas are often made of quartz glass and are also called etching rings. For their production, according to EP 3 656 746 A1, an intermediate product in the form of a hollow cylinder made of synthetically produced quartz glass is produced, from which the etching rings are then cut.

Synthetically produced quartz glass is characterized by high purity, UV transparency, chemical resistance to many substances used in the manufacturing process, and high temperature resistance. However, quartz glass is eroded by plasma in the presence of halogen-containing, in particular fluorine-containing etching gas, and because of the erosion, the roughness of the surface of the quartz glass increases and particle formation increases during the manufacturing process.

It is known that multi-component glasses containing multiple further components in addition to SiO₂, in particular rare earth metal compounds, can have increased dry etching resistance. For example, U.S. Pat. No. 6,887,576 B2 proposes increasing the dry etching resistance of quartz glass by doping with elements that can react with fluorine and form a fluoride compound whose boiling point is higher than that of SiF₄. Examples of these elements are Al, Sm, Eu, Yb, Pm, Pr, Nd, Ce, Tb, Gd, Ba, Mg, Y, Tm, Dy, Ho, Er, Cd, Co, Cr, Cs, Zr, In, Cu, Fe, Bi, Ga, and Ti.

U.S. Pat. No. 2014/0274653 A1 discloses rare earth oxide-containing, yttrium oxide-containing multi-component glasses which are characterized by higher erosion resistance to plasma erosion in comparison to quartz glass. The chemical composition of these plasma-resistant multi-component glasses is specified as follows:

| | |
|---|---|
| Yttrium oxide (Y₂O₃): | 5 wt. % to 40 wt. % |
| Aluminum oxide (Al₂O₃) | 5 wt. % to 30 wt. % |
| Silicon dioxide (SiO₂): | 10 wt. % to 80 wt. % |
| Magnesium oxide (MgO) | 1 wt. % to 20 wt. %. |

### SUMMARY

Multi-component glasses are usually produced by melting powdered raw materials and, for production-related reasons, therefore have a lower purity than glasses that can be produced “synthetically,” for example by precipitating the glass-forming components out of the gas phase. Depending on the purity of the raw materials used, multi-component glass may contain impurities that are harmful in semiconductor manufacturing.

Plasma-resistant rare earth oxide-containing multi-component glasses, as well as other technical specialty glasses, also often have a pronounced tendency to crystallize. However, during the plasma dry etching process, crystals, pores, and other inhomogeneities in the glass lead to particle formation. In order to avoid crystallization, for example, for the production of components from the plasma-resistant multi-component glasses described in U.S. Patent No. 2014/0274653 A1, it is proposed to melt a mixture of the starting components and then quench this melt, or to first melt a multi-component glass, crush it to a powder and sinter the powder at a temperature below the temperature at which the glass would melt.

However, glass is generally a poor heat conductor so that sufficiently rapid quenching from high temperatures without crystal formation is only possible with small wall thicknesses. Thick-walled rings with wall thicknesses of 10 mm and more can hardly be produced in this way. When glass powder is sintered at temperatures below the melting temperature, residual pores remain in the sintered body so that a transparent and pore-free multi-component glass is not obtained. In addition, due to the high specific surface area of glass powders, crystallization at elevated temperatures is a particularly critical effect.

The present invention is based in particular on the object of specifying a method which makes it possible to produce near-net geometry rings from a multi-component glass, even in the case of thick-walled rings with wall thicknesses of more than 10 mm.

Alternatively or additionally, the present invention is based on the object of providing a casting method for glass rings which allows for a sufficiently high cooling rate with an associated lowest possible crystal formation and, in the best case, no crystal formation, even in the case of thick-walled glass rings with wall thicknesses of more than 10 mm.

In addition, the present invention is based on the object of providing a device for carrying out the method.

Furthermore, it is an object of the present invention to provide a thick-walled ring which is made of a multi-component glass and is largely free of defects such as bubbles, inclusions, and crystals.

With regard to the method, this object is achieved by a method having the features of claim 1.

The method is used to produce a glass ring from a rare earth oxide-containing multi-component glass by casting a glass melt of the multi-component glass in a casting mold.

In a melting unit, for example in a glass melting tank or in a crucible, a glass melt is produced from the multi-component glass. Glasses that tend to crystallize, such as the multi-component glasses relevant here, must be heated to a sufficiently high melting temperature in order to obtain a homogeneous melt, to melt crystals, and/or to avoid nucleation in the glass melt. The melting temperature usually results in a low viscosity of the glass melt, which fundamentally makes its processing in the casting process more difficult. This is because, when casting low-viscosity glasses, forced convection, wrinkling and mixing of glass melts of different temperatures can easily occur, which promotes the formation of striae. Striae are material variations in the material that lead to visible differences in the refractive index of the glass.

When processing the multi-component glass by casting, the glass melt advantageously has a viscosity in the range of 10¹ dPa·s to 10⁴ dPa·s.

One or more casting strands are produced simultaneously from this low-viscosity glass melt.

Due to the force of gravity, a freely flowing glass strand usually has a vertical orientation of its longitudinal axis and, in the simplest and preferred case, directly reaches an impact zone, which is located within the casting cavity or has a fluidic connection to the casting cavity. Alternatively, the casting strand can be fed to the impact zone with a different orientation of the strand's longitudinal axis by means of a deflection element, such as a feed trough or a feed pipe.

In particular, with a view to quickly filling the casting cavity with the least possible formation of striae and crystallization, the casting strand is divided into a right-hand substream and a left-hand substream after flowing away from the impact zone.

This division halves the flow path required to close the ring or fill the casting cavity. This also means that the flow time is halved or at least reduced. This contributes to the two substreams having a roughly similar thermal history and surface temperature, also when they meet at the merging zone.

In the simplest and preferred case, the division of the casting strand into the two substreams is effected within the casting cavity. The casting strand hits the inner wall of the casting cavity and splits into the right-hand and left-hand substreams. The substreams flow around the inner wall of the casting cavity, cool down and meet again in the merging zone. In the area where the substreams converge, a characteristic process-related stria forms, which is also referred to as “casting stria” below. This casting stria can serve as a positioning marker. This is helpful for applications where, for example, a specified circumferential position of the glass ring must be maintained, or for systems were, after removal, the same glass ring must be reinstalled in the same place with the same positioning.

The low-viscosity multi-component glass cools quickly and solidifies upon contact with the walls of the casting cavity. This applies to the side walls of the casting cavity, and to the casting cavity floor. Advantageously, the supply of glass melt and any inclination of the casting cavity floor are coordinated in such a way that the two substreams fill the casting cavity as completely as possible and both cover the casting cavity floor and have contact with the side walls of the casting cavity. The casting cavity is filled optionally by a melt front, which preferably extends over the entire width of the casting cavity, moving continuously and at an approximately constant speed over already solidified melt, similarly to an avalanche. The heat-insulating effect of the already solidified multi-component glass contributes to maintaining a high temperature and low viscosity of the glass melt, so that the melt front can continue to move further toward the merging zone despite the same initial viscosity. When the casting cavity floor is completely covered with solidified glass melt, this can lead to an acceleration of the movement speed of the melt front. For adjusting the movement speed of the melt front, the inclination of the casting cavity floor relative to the horizontal can be changed during the casting process.

The impact zone, the merging zone, and the center axis of the casting mold are preferably on a line.

In particular with regard to low striae formation and crystallization, it has proven to be advantageous if the impact zone is located at an upper height level E1 and the merging zone is located at a lower height level E2.

During the casting process, the casting cavity floor of the casting mold is inclined at least temporarily relative to the horizontal such that the glass melt can flow from an impact point in the upper height level E1 in the casting cavity to the merging zone of a lower height level E2. Starting from the impact zone in the upper height level E1, the casting strand gradually fills the casting cavity. The inclination can accelerate the filling of the casting cavity with the glass melt. After the glass melt has cooled, a ring-shaped blank made of the multi-component glass can be removed from the casting mold. From this, the glass ring is obtained in the final product dimensions through further processing. Further processing may include, for example, thermal treatment to eliminate mechanical stress and/or mechanical processing by cutting, grinding, or polishing.

The impact zone is located at an upper height level E1, which is higher than the lower height level E2, in which the merging zone is located, so that an angle of inclination relative to the horizontal, which is, for example, in the range of 1° to 30°, is created between these two zones at the height levels E1 and E2. This allows the glass melt in the casting cavity to flow downward from the impact zone to the merging zone. The impact zone can be fluidically connected to the casting cavity and is located, for example, within the casting cavity. The merging zone is particularly preferably located in the casting cavity.

In this context, it has proven advantageous if the casting mold is oriented such that the casting cavity floor has an inclination relative to the horizontal between the height levels E1 and E2, wherein the inclination is changed during the casting process.

The height difference between the height levels E1 and E2 can be created by an orientation of the entire casting mold in space that is inclined relative to the horizontal and/or by a structural design of the casting cavity floor with a downward-sloping ramp or with multiple downward-sloping ramps. The height difference can remain constant during the casting process, but it is preferably varied during the casting process. In a preferred method variant, a higher angle of inclination is set at the beginning of the casting process and is reduced at least temporarily during the casting process.

In the simplest case, the casting cavity floor is flat in cross-section between the casting cavity side walls. In an alternative approach, a casting cavity floor is provided which is U-shaped or V-shaped in cross-section between the casting cavity side walls over a partial section so that it guides the two diverged substreams in the center thereof. This can delay the point in time at which the glass melt touches the inner or outer wall of the casting cavity. In this embodiment, too, the casting mold preferably has an inclination relative to the horizontal between the height levels E1 and E2, wherein the inclination can be changed during the casting process.

The temporal change of the inclination of the entire casting mold relative to the horizontal is preferably carried out by means of a controlled or regulated mechanism. The inclination is preferably reduced during the casting process.

The inclination of the casting mold is preferably controlled such that a build-up of the glass mass is prevented, in particular in the area of the impact zone, and that trouble-free merging of the glass strands in the area of the merging zone is achieved. For this purpose, an inclination of, for example, in the range of 1 to 30 angular degrees has proven to be advantageous.

A permanent inclination can lead to an inconstant height of the glass ring so that the formed glass ring is higher in the area of the merging zone than in the area of the impact zone. However, by gradually reducing the inclination, possibly until the horizontal position is reached before the end of the casting process, the generally undesirable difference in height can be equalized.

The change in the inclination of the casting mold is usually stopped when the horizontal orientation of the casting cavity floor is reached. The speed at which the inclination of the casting mold is changed is preferably constant; however, it may also be variable. In particular, the speed may be higher at the beginning of the casting process than at the end. Preferably, the inclination of the casting mold is only changed after the two substreams have merged for the first time.

The variable inclination of the casting mold, in particular of the casting cavity floor, facilitates trouble-free merging of the glass strands in the merging zone.

In this context, it has also proven advantageous if the position of the impact zone is variable during a first casting phase. At the beginning, it is preferably located on a ramp that slopes downward from the outside to the inside, toward the inner wall of the casting cavity. During a second casting phase, the position of the impact zone on the ramp is changed and preferably shifted outward, away from the inner wall of the casting cavity.

The ramp may extend along a partial length of the outer circumference of the casting cavity. For example, it is wedge-shaped when viewed from above, wherein the surface of the wedge shape transverse to the direction of the slope is either straight or can have a curvature. The ramp can be considered as part of the casting cavity or the casting cavity floor. It creates a higher slope in the area of the impact zone. This means that the arriving glass melt is deflected at an angle that is greater than the angle of inclination of the rest of the casting cavity floor but less than 90°, which supports the flow of the glass melt away from the impact zone. The slope of the ramp can be described with a “ramp angle,” with the average ramp angle preferably being in the range of 1 to 60 degrees, preferably in the range of 25 to 45 degrees. In the simplest and preferred case, the slope of the ramp is constant. However, it can also have another concave or convex shape in at least one axis, but always a monotonically descending shape.

The casting process can be divided into multiple casting phases. During the first casting phase, the glass melt flows out onto the casting mold floor and fills the floor region. During this phase, there is no or only a slight build-up of glass height in the area of the impact zone. This can remain in the same place but oscillating back and forth movements of the casting strand are also possible. These oscillating back and forth movements, which shift the impact zone, are small and typically range from 1 to 10 mm.

The end of the first casting phase, for example, is characterized by the point in time at which the diverged substreams merge for the first time, so that the glass melt, or rather the glass ring, which continues to flow, also builds up in height. The second casting phase is thus characterized by the movement of the glass melt also upward and the beginning of the height build-up of the glass ring. This means that the glass melt runs over the lower, partially cooled glass into the casting mold and fills most or all the casting cavity. Any existing inclination of the casting mold can then be reduced (to the horizontal and possibly even briefly beyond) to level out any thickness differences from the first casting phase, with the aim of largely equalizing the filling level in the entire casting cavity.

In the second casting phase, a relative movement can also take place between the casting strand and the casting mold, more precisely: between the impact zone and the casting cavity. In the second casting phase, for example, the position of the impact zone is shifted outward, advantageously on an “ascending ramp,” away from the inner wall of the casting cavity. This outward shift of the impact zone on the “ascending ramp” may occur from time to time, but preferably continuously, preferably in the direction of a connecting line between the impact zone and the merging zone. The speed of the shift on the ascending ramp is constant or variable during the second casting phase and is preferably in the range of 1 mm/min to 100 mm/min, preferably in the range between 1 and 30 mm/min.

The connecting line between the impact zone and the merging zone advantageously runs through the center line of the ring-shaped casting cavity. In this case, the right-hand and left-hand substreams are of equal length and the merging zone is located at the lowest point of the casting cavity in the plane E2. If the formation of a merging zone above the plane E2 becomes apparent during the casting process, this can be advantageously counteracted by shifting the impact zone relative to the casting mold. The impact zone can be shifted in the azimuthal direction along the ring-shaped casting cavity circumference, or more simply and therefore preferably: by lateral movement of the casting mold perpendicular to the above-mentioned connecting line, or by inclining the casting mold around and along the connecting line (i.e., by lateral tilting) or by rotating the casting mold (e.g., around the center of the ring-shaped casting cavity). During the relative shift of the impact zone, the height distance between an outlet of the glass strand and the impact point is advantageously kept constant. This means, for example, in the case of an impact zone reaching a ramp with a slope, that the relative shifting movement of the impact zone follows the (straight or curved) shape of the ramp in the shifting direction.

The term “casting process” refers here and below to the entire method step of casting the glass melt into the casting mold, which comprises the first and second casting phases and optionally a third casting phase. A third casting phase can include measures taken after the casting mold has been completely filled, to complete the actual casting process.

As a result of the shifting of the impact zone along the ascending ramp, the casting cavity continues to fill with glass melt in the course of the second casting phase and the vertical distance between an outlet for the casting strand and the surface of the glass melt in the impact zone may shorten. To keep this distance constant, the casting mold is advantageously lowered during the second casting phase.

As a result of the, preferably continuous, shifting of the impact zone and the, preferably continuous, lowering of the casting mold, the glass melt is deflected from the impact zone into the casting cavity such that the meniscus of the glass melt flowing into the casting cavity remains approximately constant despite the melt level spreading and filling the casting cavity.

During the casting process, the ramp usually forms a closed surface which the casting strand hits. In a preferred variant of the method, however, the ramp can be opened and closed and optionally equipped with a closable opening. Before the casting cavity filling begins, the opening is open so that the casting strand falls downward through it. By closing the opening, the casting strand is cut off and diverted from a vertical fall direction from the ramp toward the casting cavity floor.

The opening and closing of the opening of the ramp is carried out, for example, by means of a part of the ramp which is movable horizontally and radially in the direction of a casting mold center axis and is referred to below as the “slider.” The slider can be considered as part of a multi-part ramp or as part of a multi-part casting mold. When the ramp is open, the slider is positioned at a distance from the rest of the casting mold, leaving a “casting gap” free. In this case, the casting gap forms the opening of the ramp. At the beginning of the casting process, the ramp (the casting gap) is open and the casting strand runs freely downward through the casting gap. There, it is collected in a container, for example. By pushing the slider toward the rest of the casting mold, the casting gap is closed. The originally vertically oriented casting strand is cut off as if with scissors, hits the ramp in the impact zone and then flows further down the ramp at an angle of less than 90 degrees, as explained in more detail above with reference to the description of the ramp. When closed, the slider forms part of the ramp.

A first advantageous function of the slider is thus to close the casting gap and separate the glass strand flowing vertically through the casting gap from above. A second advantageous function of the slider is to deflect the glass strand in the direction of the casting mold center axis so that the outflow of the substreams is redirected from the impact zone toward the merging zone. It has also proven helpful if the slider is adjacent to the casting cavity floor when the casting gap is closed, and, for example, touches the periphery of the casting cavity floor tangentially.

The flow rate of glass melt is preferably metered in a range of 150 ml/min to 3000 ml/min, particularly preferably in the range of 300 ml/min to 1500 ml/min. It is preferably constant during a casting process, but it can also be variable.

The method according to the present invention is particularly suitable for processing glass melts with a low viscosity. The viscosity during feeding is preferably in the range of 10 to 10,000 dPa·s, particularly preferably in the range of 100 to 1,000 dPa·s.

The inflowing glass melt heats the casting mold in the course of the casting process. To counteract rapid cooling of the glass melt on the walls of the casting cavity, at the beginning of the casting process, it has proven advantageous to heat the casting mold.

Heating the casting mold has proven to be advantageous for reducing high heat loss of the glass melt at the walls of the casting cavity. Heating is preferably carried out electrically, for example inductively, by radiant heating or by means of heating cartridges. The heating temperature depends on the temperature/viscosity profile of the given glass. For example, it lies in the range of the so-called transformation or glass formation temperature Tg or lower, for example in the temperature range from Tg-300° C. to Tg. Heating reduces the risk of crack formation during cooling of the glass ring and has a positive effect on the flow properties by preventing excessively rapid cooling below Tg. Alternatively, or additionally, thermal insulation of the casting mold is also advantageous, for example by placing refractory material above the casting mold or by actively heating the glass melt in the casting mold from above, for example by means of a gas flame or a porous burner.

In a preferred method variant, the inner wall of the casting cavity and/or the outer wall of the casting cavity is conical and movable in the vertical direction relative to the casting cavity floor.

The inner wall is formed, for example, by a lowerable cylinder or ring, preferably a conc. During the cooling of the glass melt, the cylinder/cone (i.e., the inner wall of the casting cavity) can preferably be moved vertically by a few millimeters, thus creating a gap between the solid glass body and the inner wall of the casting cavity. In the case of the conical inner wall, it is irrelevant whether the cone is tapered upward or downward: The vertical movement during cooling always occurs in such a way that the diameter of the inner wall is reduced in comparison to the inner diameter of the glass ring, thus forming a gap and thus avoiding wedging when removing the glass ring from the casting mold.

With regard to the device for producing a glass ring from multi-component glass, the above-mentioned object is achieved by a device having the features of claim 11.

The device comprises
(a) a casting mold comprising a ring-shaped casting cavity, which runs around a center axis, has a casting cavity height and has a casting cavity floor, which is delimited by an inner wall and an outer wall, and, opposite thereto, a casting cavity opening;
(b) an outlet for supplying a melt of the glass to the casting mold; and,
(c) a movement unit for the spatial movement of the outlet and/or of the casting mold.

The movement unit serves to position the casting mold at a specified location and/or in a specified orientation with respect to the outlet, and/or to move the casting mold along a specified path of movement relative to the outlet. The necessary positioning and movements of the casting mold or outlet are preferably carried out by the movement unit in a computer-controlled manner.

For this purpose, the movement unit preferably has means for rotating and tilting components, such as joints and axes of rotation, and it has means for translationally displacing components in the three spatial directions x, y, z, where “z” here represents the height direction, such as linear units.

This device has displacement, tilting, rotating, and/or sliding functions. In particular, it is possible to position a casting strand emerging from the outlet, such that it hits an impact zone and flows from there toward the inner wall of the casting cavity, where it divides into a right-hand substream and a left-hand substream. The substreams flow together at a merging zone in the casting cavity, as explained above in the description of the method according to the present invention.

The impact zone is preferably located at an upper height level E1 and the merging zone at a lower height level E2.

The device is suitable for carrying out the method according to the present invention. Advantageous embodiments of the device according to the present invention can be found in the dependent claims. To the extent that embodiments of the device specified in the dependent claims are patterned on the methods mentioned in the dependent claims for the method according to the present invention, reference is made, for supplementary explanation, to the above statements regarding the corresponding method claims.

With regard to the glass ring made of multi-component glass, the above-mentioned object is achieved by a glass ring having the features of claim 16.

This glass ring can be produced using the method according to the present invention. The substreams flowing around the inner wall of the casting cavity and meeting in the merging zone form a casting stria in the area of the azimuthal position of the merging zone, which stria partially or preferably completely passes through the ring cross-section in the radial direction. The optical detectability of the casting stria in the glass ring is improved if it causes an optical path difference of at least 30 nm in the multi-component glass.

Since only a single casting stria is present in the entire ring cross-section, this can serve as a positioning marker. This is helpful for applications where for example, a specified circumferential position of the glass ring must be maintained, or for systems where after removal, the same glass ring must be reinstalled in the same place with the same positioning.

The multi-component glass is characterized by a high purity, which is exemplified by the fact that impurities of Cr, Mn, Fe, Co, and Ni and compounds for each of these elements individually are less than 50 ppm by weight and particularly preferably less than 20 ppm by weight, and that the sum of the impurities of Cr, Mn, Fe, Co, and Ni is less than 100 ppm by weight.

In addition, the high-purity multi-component glass is characterized by high dry etching stability in reactive ion etching processes (RIE for short) in comparison to quartz glass.

The glass ring is therefore suitable as a plasma etching ring for holding wafers during plasma-assisted dry etching treatment. It typically has an outer diameter in the range of 300 to 500 mm, a wall thickness of more than 10 mm and a height of at least 5 mm.

Individual terms in the above description are further defined below. The definitions are part of the description of the present invention. For terms and measurement methods that are not specifically defined in the description, the interpretation according to the International Telecommunication Union (ITU) shall apply. In the event of an inconsistency between one of the following definitions and the rest of the description, the statements made elsewhere in the description take precedence.

The multi-component glass consists of at least three components. In the simplest and preferred case, it is a purely oxidic glass in which all anions consist of oxygen ions (O²⁻). The oxygen ions may occupy 100% of the anion sites in the network structure of the glass. In another, equally preferred embodiment, a portion of the oxygen ions is substituted by fluorine ions. In this case, the multi-component glass has a network structure with anion sites, wherein (100-x) % of the anion sites are occupied by oxygen ions (O²⁻) and the fraction x (%) is occupied by fluorine ions (F), where x is the degree of substitution (in %) and is in the range between 0.1 and 10.

The ramp can be considered as part of the casting cavity and also as part of the lateral boundary of the outer wall of the casting mold. The ramp has a slope in the direction of the casting mold center line and serves to deflect the glass flow emerging from the outlet tube, so that the glass strand is directed from a vertical orientation on the casting cavity floor toward the inner wall of the casting cavity. For this purpose, the ramp can be equipped with a closable casting gap.

The processing of the multi-component glass takes place in a liquid, low-viscosity state, which is characterized by a viscosity in the range of 101 dPa·s to 10+dPa·s, preferably by a viscosity in the range of 102 dPa·s to 103 dPa·s. This viscosity range is typically achieved for multi-component glass at temperatures in the range of 900° C. to 1500° C. The measurement of viscosity is carried out by shear or rotational viscometry according to DIN ISO 7884-2 (1998). Instead of the exponential notation, viscosity values are often also specified using the common logarithm in the form log (dPa·s).

Striae are spatially limited fluctuations in the material homogencity in a glass, which cause a local difference in refractive index. The dimensions are short-range and in the range of approx. 0.1 mm to approx. 2 mm. Differences in refractive index (optical path differences) are usually only visually noticeable from 30 nm.

Striae can therefore be characterized as an optical feature. The casting stria that occurs at the junction of the substreams is the totality of many small defects (striae) that are aligned along the radius of the glass ring. The individual striae have a small extent in the circumferential direction but they have a comparatively large area extending to the outer edges of the glass ring.

For the optical identification of striae at the position of the casting stria, the shadow method is suitable, as described in the brochure “Technical information for optical devices TIE-25:Striae in optical glass” by Schott AG, June 2006.

For measuring the dry etching resistance, a sample of the multi-component glass is subjected to a standard dry etching procedure in an RIE plasma reactor with the following treatment steps:
(a) One flat side of the test sample is polished so that it has a surface roughness with an Rₐ value of 4 nm or less.
(b) A surface portion of the polished flat side is masked with a varnish.
(c) The polished flat side is subjected to a dry etching procedure characterized by the following parameters:
   A power of 600 watts is fed into the HF energy source.
   Using the HF energy source, a bias voltage of minus 100 volts is applied to the test sample at an input power of 10 watts.
   The following process gases are introduced into the reactor chamber: 5 sccm argon, 1 sccm CF₄, 0.3 sccm O₂.
   The chamber pressure is set to 6 Pa.
   The etching time is 60 minutes.

At an etching rate of less than 50% in comparison to a reference sample made of synthetic quartz glass (Suprasil; trade name of Heraeus Quarzglas GmbH & Co. KG), the multi-component glass is classified as dry etching resistant.

A multi-component glass is defined here as “high purity” if the fraction of impurities of Cr, Mn, Fe, Co, and Ni and compounds for each of these elements individually in the multi-component glass is less than 50 ppm by weight, and if the sum of the impurities of Cr, Mn, Fe, Co, and Ni is less than 100 ppm by weight.

### BRIEF DESCRIPTION OF THE DRAWINGS

The present invention is explained in more detail below with reference to an exemplary embodiment and a drawing. In detail, in a schematic representation,

FIG. 1 shows a casting mold mounted on a frame for producing a glass ring, in a three-dimensional view;

FIG. 2 shows a detail of the casting mold and frame in a side view in section along the line AA′ of FIG. 1;

FIG. 3 shows a sketch for explaining the height levels and inclination of the casting mold;

FIG. 4 shows a sketch for explaining the impact zone and merging zone when casting a glass ring; and,

FIGS. 5 to 12 show sketches for explaining the method steps for producing the glass ring.

### DETAILED DESCRIPTION OF THE INVENTION

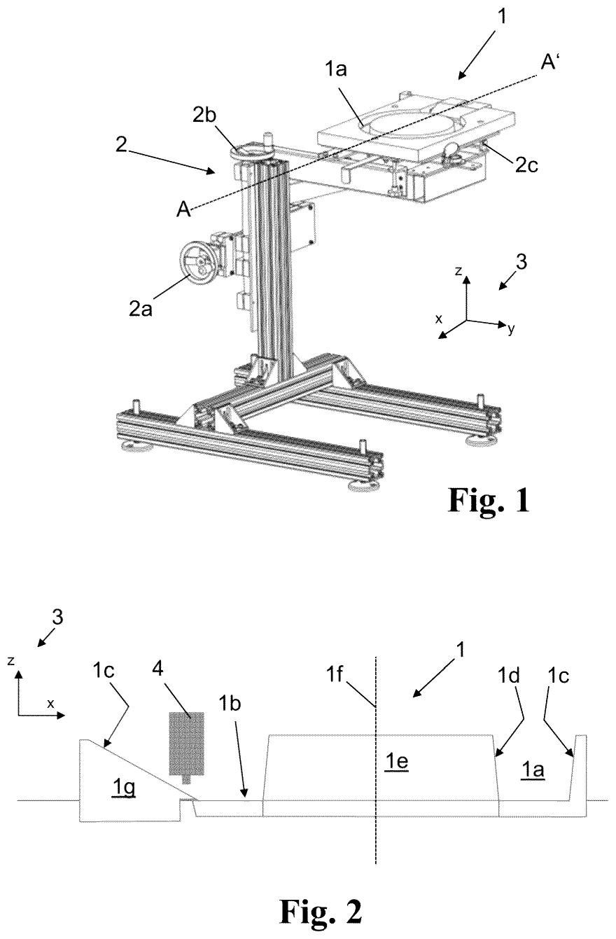

FIG. 1 schematically shows an embodiment of the device of the present invention with a casting mold 1 mounted on a frame 2. The frame 2 is equipped with a linear unit 2a for positioning the casting mold 2 in the height direction (z direction) and a further linear unit 2b for the translational movement of the casting mold 2 within a plane (in the x direction). Furthermore, the frame 2 has an electrically movable joint 2c for adjusting the inclination of the casting mold 1. The directions are shown by the coordinate system 3. The movements of the casting mold 1 by means of the linear units 2a, 2b and the tilting of the casting mold 1 by means of the joint 2c are carried out in a computer-controlled manner.

The device is used to produce a glass ring from a high-purity multi-component glass by casting a glass melt into the casting mold 1. The casting mold 1 has a circular, closed casting cavity 1a which is open at the top. A stationary outlet tube 4 (FIG. 2) is positioned above the casting cavity 1a. Glass melt is supplied to the outlet tube 4 from a conventional melting crucible (not shown).

Further details of the casting mold 1 are visible in FIG. 2 The casting cavity 1a has, opposite the gap opening, a circular casting cavity floor 1b, which is bounded on the outside by a ring-shaped outer wall 1c and on the inside by an inner wall 1d. The outer diameter of the casting cavity 1a is 360 mm, the inner diameter is 300 mm, and the height is 30 mm.

The inner wall 1d is formed by an insert body 1e, which tapers slightly conically toward the top. During the casting process, the insert body 1e closes off a central opening of the casting mold 1, which runs coaxially with the center axis 1f. After the casting process, it is pushed downward (y direction) out of the central opening.

A part of the outer wall 1c or a part of the casting cavity floor 1b is formed by a wedge-shaped body 1g which is displaceable in the radial direction (x direction) and which is arranged before the casting process such that it leaves a casting gap from the casting mold 1. The functions of the wedge-shaped body 1g and the casting gap are explained in more detail below using the method and FIGS. 6 to 12.

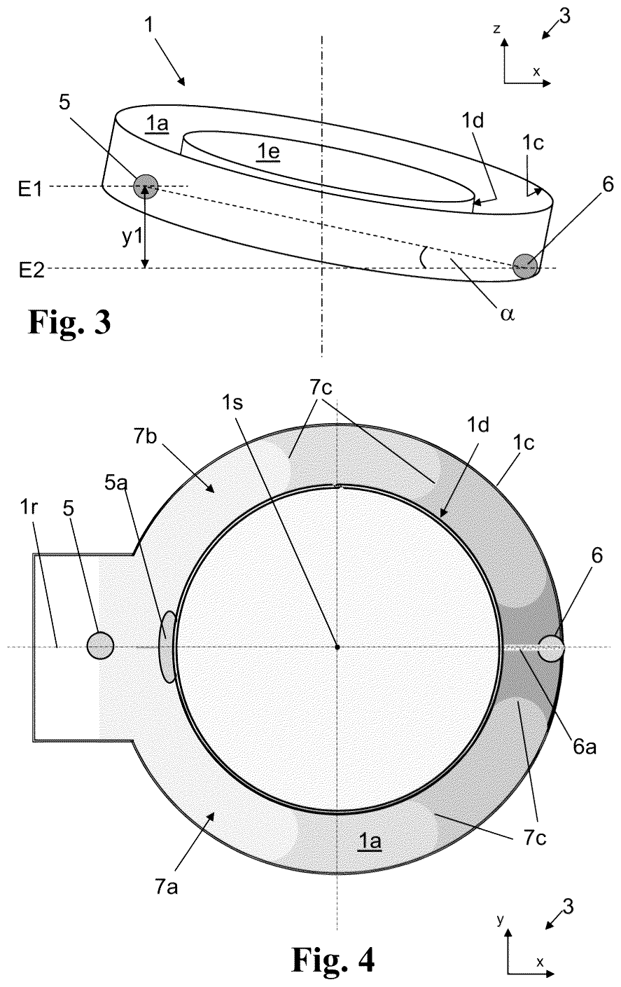

At the beginning of the casting process, the casting mold 1 is oriented in space such that the casting cavity floor 1b has an inclination relative to the horizontal. This is indicated in the sketch of FIG. 3 by the tilt anglea.

The casting mold 1 is positioned under the outlet tube 4 (FIG. 2) such that an initial impact zone 5 of the casting strand is formed at the height level E1. From there, the casting strand flows into the casting cavity 1b and reaches the casting cavity inner wall 1d, which acts as a “watershed” for the glass melt so that the casting strand divides into a right-hand substream 7a and a left-hand substream 7b. This schematically indicated division zone 5a lies in the area of the intersection point between the inner wall 1d of the casting cavity and the center line 1r of the casting mold 1 included in the plan view of FIG. 4. The two substreams 7a; 7b flow downward in the casting cavity 1b according to its inclination and merge in a merging zone 6, which is located at a height level E2. The impact zone 5, the division zone 5a, the merging zone 6, and the center axis 1s of the casting mold 1 running perpendicularly to the sheet plane lie on the center line 1r. Over time, the casting cavity 1a fills with glass melt, forming a casting stria 6a in the area of the merging zone 6. Small defects, such as small striae, can be seen in the casting stria 6a. The casting stria 6a forms the visually recognizable totality of these smaller striae.

The initial inclination of the casting cavity floor 1b in the exemplary embodiment is 15 angular degrees and, at a distance of 370 mm between the impact zone 5 and the merging zone 6, results in a height difference yl between the height level E1 at the raised end of the casting cavity floor 1b and the height level E2 at the opposite end of the casting cavity floor 1b of approximately 61 mm.

The method according to the present invention is explained in more detail below using an example with reference to FIGS. 1 to 12:

The glass ring 13 (FIG. 12) to be produced by casting has an outer diameter of 360 mm, an inner diameter of 300 mm, and thus a wall thickness of 30 mm and a height of 25 mm. The casting cavity 1a of the casting mold 1 is designed accordingly.

A glass melt with the following composition is melted in a crucible:

| | Fraction |
|---|---|
| Component | (mol %) |
| SiO₂ | 57 |
| Al₂O₃ | 15 |
| Y₂O₃ | 10 |
| MgO | 18 |

At the melting temperature of approximately 1380° C., the glass has a viscosity of approximately 100 dPa·s.

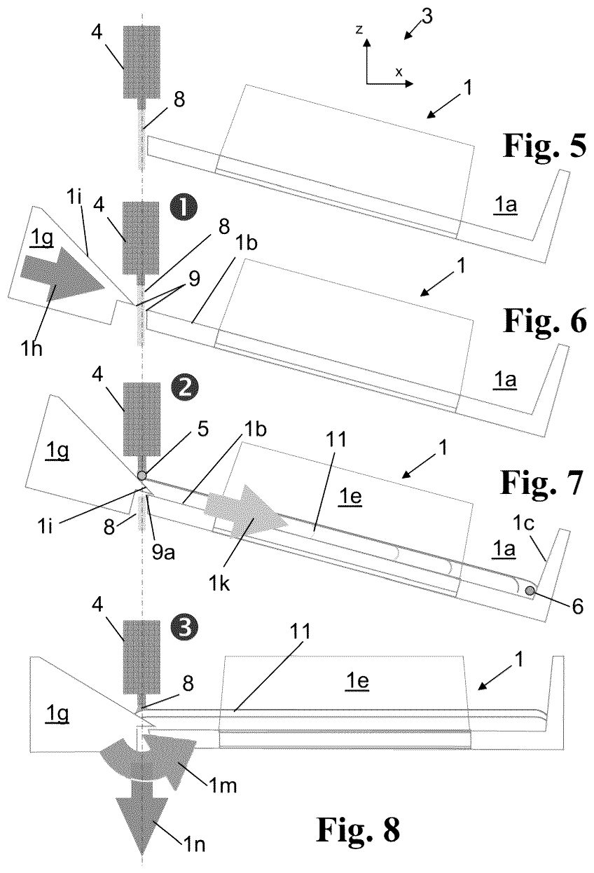

FIG. 5 schematically shows the casting mold 1, the outlet tube 4, and a casting strand 8 flowing out of the outlet tube 4 in a vertical direction past the casting mold 1. The casting mold 1 initially has an inclination of 15 degrees relative to the horizontal. A stable jet with a flow rate of 1000 ml/min is established before proceeding. The unused glass mass is collected in a container.

FIG. 6 schematically shows a method step (1), in which a wedge 1g is pushed in the radial direction toward the casting strand 8, as indicated by directional arrow 1h. The upper side of the wedge 1g facing the casting mold 1 forms a ramp 1i sloping downward toward the casting mold 1. The casting strand 8 initially continues to fall through a casting gap 9, which is formed between the ramp 1i and the casting cavity floor 1b of the casting mold 1.

FIG. 7 shows a method step (2), in which the ramp 1i finally closes the casting gap 9 by further pushing the body 1g forward and thereby interrupts the casting strand 8. Said casting strand hits the ramp 1i (FIG. 6) in the area of an initial impact zone 5 and is deflected from there onto the casting cavity floor 1b (FIG. 4), as indicated by directional arrow 1k. This begins a first casting phase. The vertical casting strand 8 hits the initial impact zone 5 at the height level E1, divides in the division zone 5a into two substreams 7a, 7b (FIG. 4), which flow around the insert body 1e and merge again in the area of the merging zone 6 at the lower height level E2, forming the casting stria 12.

The initial impact zone 5 lies on the surface of the wedge 1i, which forms a downward-inclined ramp for the glass melt 11 flowing into the casting mold, with an inclination of 30 angular degrees relative to the casting mold floor. Together with the angle of inclination of 15 angular degrees due to the initial inclination of the casting mold floor 1b, this results in an impact surface for the casting strand 8 at the initial impact zone 5 that is inclined downward by 45 angular degrees relative to the horizontal.

The glass melt 11 cools on the walls of the casting cavity 1a, in particular on the casting cavity floor 1b, and solidifies. As the casting cavity 1a continues to be filled, a melt front 7c, indicated in FIG. 4 by arcuate gray regions, which extends over the entire width of the casting cavity 1a, moves continuously and at an approximately constant speed over the already solidified melt further toward the merging zone 6. Layering the glass melt as evenly as possible prevents convection and the associated striae.

As soon as the casting cavity floor 1b is completely covered with solidified glass melt, this leads to the merging of the two melt fronts 7c in the merging zone 6. For reducing the speed of movement of the melt front 7c, the inclination of the casting cavity floor 1b relative to the horizontal is continuously reduced by approximately 15 degrees/min.

As a result, in method step (3), the casting mold 1 is gradually brought into a horizontal orientation, as shown schematically by directional arrow 1m in FIG. 8, and a second casting phase begins. The pivot point of the tilting movement is stationary and lies in the outlet area of the outlet tube 4.

At the same time, the casting mold 1 is continuously lowered relative to the stationary outlet tube 4 at a speed of approximately 15 mm/min, as indicated by directional arrow 1n, and moved along the contour of the ramp such that the outlet tube 4 maintains a largely constant distance of approximately 3 to 5 mm from the level of the glass melt 11.

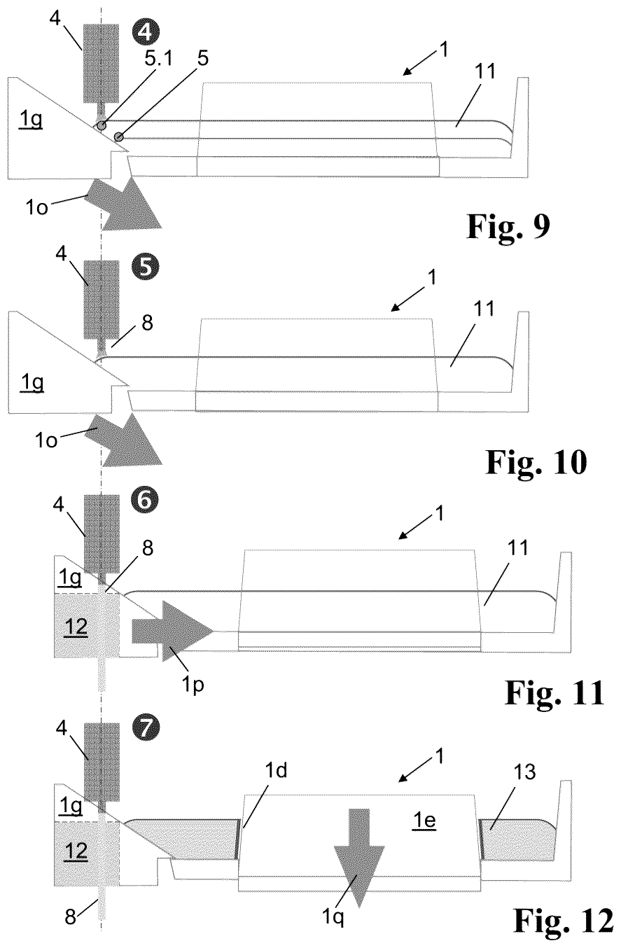

FIG. 9 schematically shows a method step (4), in which the casting mold 1 together with the casting cavity floor 1b (FIG. 4) has reached a horizontal orientation. The glass melt 11 in the area of the initial impact zone 5 has cooled to a temperature below the softening temperature of the glass and is flooded by a further, low-viscosity glass melt 11 so that a horizontal melt surface is formed. By continuously lowering the casting mold 1 relative to the outlet tube 4 (directional arrow 1n in FIG. 8) and by successive translational displacement of the casting mold 1 as indicated by directional arrow 10, a new impact zone 5.1 for the casting strand 8 has been created, which continues to be located at approximately the same distance above the ramp 1i of the wedge-shaped body 1g. The new impact zone 5.1 is permanently located at the edge of the forming glass ring so that the flow direction of the glass melt 11 is always directed toward the center of the casting mold, or at most is deflected to the side, but no glass melt flows in the opposite direction.

The casting process is continued until the glass melt 11 has filled the casting cavity 1 to such an extent that the height of the glass ring 13 to be produced (FIG. 12) is reached. This state (method step (5)) is shown in FIG. 10.

The subsequent method step (6) can be referred to as the third casting phase, in which the end of the casting process is initiated by the casting strand 8 still flowing out of the outlet tube 4 being guided away from the ramp of the insert body 1g by virtue of the wedge-shaped body 1g, together with the remaining casting mold 1, as indicated FIG. 11 by directional arrow 1p, being displaced such that it reaches the area of a recess 12 in the insert body 1g and falls vertically downward into the collecting container.

The movements of the casting mold 1 and of the wedge-shaped body 1g in the method steps (1) to (6) as explained with reference to FIGS. 5 to 11 are carried out in a computer-controlled manner.

In the course of the further cooling of the glass melt 11, the conical insert body 1e is lowered by a few millimeters (method step (7)), as indicated by directional arrow 1q of FIG. 12. This prevents the hot glass ring 13 from shrinking onto the inner wall 1d.

The resulting ring-shaped glass blank 13 is tempered in a stress-free manner and ground to the desired dimensions of the glass ring, which are almost already achieved by the near-net-shape forming in the casting process.

This results in a glass ring made of high-purity multi-component glass, which is characterized by high transparency, high purity, and high plasma resistance.

The high purity of the multi-component glass is demonstrated by the fact that the fraction of impurities of Cr, Mn, Fe, Co, and Ni and compounds for each of these elements individually in the multi-component glass is less than 50 ppm by weight, and that the sum of the impurities of Cr, Mn, Fe, Co, and Ni is less than 100 ppm by weight.

The high plasma resistance of the multi-component glass is demonstrated by the fact that, when carrying out the standard dry etching procedure, it has an etching rate that is less than 25% of the etching rate of synthetically produced quartz glass (Suprasil).

The glass ring shows a characteristic casting stria 6a (FIG. 4), which extends over a partial or the entire cross-section (the entire width and the entire height) of the glass ring in the area of the former merging zone 6. The casting stria 6a has a circumferential extension of less than 2 mm and causes an average path difference of more than 30 nm in the multi-component glass for a measuring beam with a measuring wavelength of 535 nm. It can serve as a position marker in a system, such as a plasma etching system for semiconductors.

What is claimed is:

1. A method for producing a glass ring from multi-component glass, wherein a ring-shaped blank is produced from the multi-component glass by means of a casting process comprising the following method steps:
(a) providing a casting mold comprising a ring-shaped casting cavity, which runs around a center axis (1s), has a casting cavity height, and has a casting cavity floor, which is delimited by an inner wall (1d) and an outer wall, and, opposite thereto, a casting cavity opening;
(b) producing a glass melt of the multi-component glass;
(c) feeding a casting strand of the glass melt into the casting mold, wherein the casting strand hits an impact zone and diverges into a right-hand substream and a left-hand substream, and wherein the substreams converge at a merging zone in the casting cavity and fill the casting cavity over at least part of the casting cavity height; and,
(d) cooling the glass melt contained in the casting cavity, to form a ring-shaped blank, and further processing the ring-shaped blank to form a glass ring.

2. The method according to claim 1, wherein the impact zone is located at an upper height level E1, and in that the merging zone is located at a lower height level E2, wherein the casting mold is preferably oriented such that the casting cavity floor has an inclination relative to the horizontal between the height levels E1 and E2, wherein the inclination is changed during the casting process.

3. The method according to claim 2, wherein the position of the impact zone during a first casting phase is located in the area of a ramp sloping downward from the outside to the inside, and in that, during a second casting phase, the position of the impact zone on the ramp is changed, preferably shifted outward, wherein the casting mold is preferably lowered during the second casting phase.

4. The method according to claim 3, wherein the ramp can be opened and closed, wherein the casting strand is cut off by closing the ramp and diverted from a vertical fall direction onto the casting cavity floor.

5. The method according to claim 1, wherein the casting strand is metered to a flow rate in the range of 150 ml/min to 3000 ml/min, preferably in the range of 300 ml/min to 1500 ml/min.

6. The method according to claim 1, wherein the glass melt is conditioned to a feed viscosity in the range from 10 to 10,000 dPa·s, particularly preferably in the range from 100 to 1,000 dPa·s.

7. A device for producing a glass ring from glass by casting a glass melt, comprising:
(a) a casting mold comprising a ring-shaped casting cavity, which runs around a center axis, has a casting cavity height, and has a casting cavity floor, which is delimited by an inner wall and an outer wall and, and, opposite thereto, a casting cavity opening; and,
(b) an outlet for supplying a melt of the glass to the casting mold, wherein the device has a movement unit for the spatial movement of the outlet and/or of the casting mold, by means of which unit the casting mold can be moved relative to the outlet and positioned such that a casting strand emerging from the outlet tube hits an impact zone and diverges into a right-hand substream and a left-hand substream, and the substreams converge at a merging zone in the casting cavity.

8. The device according to claim 7, wherein the movement unit is designed to adjust an inclination of the casting mold relative to the horizontal in such a way that the impact zone is located at an upper height level E1 and the merging zone is located at a lower height level E2.

9. The device according to claim 7, wherein the movement unit is designed to lower the casting mold relative to the outlet.

10. The device according to claim 9, wherein the casting cavity floor comprises a ramp having an opening that can be closed by means of a movable slider.

11. A glass ring made of multi-component glass, which glass ring has a center line and a cross-section, which is defined by an upper side, a bottom side opposite thereto, an outer wall and an inner wall, and which has at an azimuthal position a radial casting stria, which extends, with respect to the center line, in the radial direction in the area between the inner wall and the outer wall.

12. The glass ring according to claim 11, wherein the casting stria completely fills the cross-section between the upper side, bottom side, outer wall, and inner wall.

13. The glass ring according to claim 11, wherein the casting stria produces a path difference of at least 30 nm for a measuring beam with a wavelength of 535 nm.

14. The glass ring according to claim 11, wherein it has an outer diameter in the range of 300 to 500 mm and a wall thickness of at least 10 mm.

15. The glass ring according to claim 11, wherein the fraction of impurities of Cr, Mn, Fe, Co, and Ni and compounds for each of these elements individually in the multi-component glass is less than 50 ppm by weight and particularly preferably less than 20 ppm by weight, and in that the sum of the impurities of Cr, Mn, Fe, Co, and Ni is less than 100 ppm by weight.

16. The method according to claim 2, wherein the glass melt is conditioned to a feed viscosity in the range from 10 to 10,000 dPa·s, particularly preferably in the range from 100 to 1,000 dPa·s.

17. The method according to claim 3, wherein the glass melt is conditioned to a feed viscosity in the range from 10 to 10,000 dPa·s, particularly preferably in the range from 100 to 1,000 dPa·s.

18. The method according to claim 4, wherein the glass melt is conditioned to a feed viscosity in the range from 10 to 10,000 dPa·s, particularly preferably in the range from 100 to 1,000 dPa·s.

19. The method according to claim 5, wherein the glass melt is conditioned to a feed viscosity in the range from 10 to 10,000 dPa·s, particularly preferably in the range from 100 to 1,000 dPa·s.

20. The device according to claim 8, wherein the movement unit is designed to lower the casting mold relative to the outlet.
